(19) United States
(12) Patent Application Publication
(10) Pub. No.: US 2003/0212948 A1
(43) Pub. Date: Nov. 13, 2003

(54) Synchronization scheme in a turbo decoder based FEC system

(76) Inventors: Mustafa Eroz, Germantown, MD (US); Bharath Venkataraman, Germantown, MD (US); Feng-Wen Sun, Germantown, MD (US); Lin-Nan Lee, Potomac, MD (US); Arjun Punshi, San Diego, CA (US)

Correspondence Address: Hughes Electronics Corporation, Patent Docket Administration, Bldg. 1, Mail Stop A109, P.O. Box 956, El Segundo, CA, 90245-0956, US

(21) Appl. No.: 10/140,345

(22) Filed: May 7, 2002

(51) Int. Cl. H03M 13/03

(52) U.S. Cl. 714/789

(57) ABSTRACT

A system and method for detection of frame synchronization in turbo encoded and concatenated forward error correction (FEC) systems. The system and method provides a configurable conditional synchronizer module monitoring turbo decoder input data, with an additional first synchronization check module monitoring turbo decoder output data, and an additional second synchronization check module monitoring block code decoder output data in concatenated systems. Conditional synchronization found by the configurable conditional synchronizer is reset when either check module one or two detects a loss of sync, thus reducing the probability of false synchronization locks.

### BACKGROUND OF THE INVENTION

1. Field of the Invention

The present invention relates to frame synchronization in turbo encoded and concatenated forward error correction (FEC) systems. Specifically, the present invention relates to a system and method providing a configurable conditional synchronizer with an additional first synchronization check module monitoring turbo decoder data output, and an additional second synchronization check module monitoring block code decoder data output in concatenated systems. Conditional synchronization found by the configurable conditional synchronizer, is reset when either check module one or two detects a loss of sync, thus greatly reducing the probability of false locks.

2. Description of the Related Art

Forward error correction (FEC) is necessary in systems to provide high quality communication over radio frequency (RF) propagation channels, which may induce distortions in the signal waveform. Such distortions may include signal attenuation and multi-path fading, to name a few. Addressing such distortions often plays a large role in the design of radio transmission and receiver equipment in which, a key design objective is the selection of components that mutually operate to provide balance between performance and complexity. However, differences in propagation channel characteristics can also result in significantly different system designs. Therefore, communications systems continue to evolve to satisfy higher system requirements for faster data rates and greater communication services.

One method of forward error correction involves the use of turbo codes, which have been demonstrated to yield bit error rate (BER) performance close to the theoretical limit for useful classes of idealized channels. A turbo encoder consists of a parallel concatenation of two or more recursive, or feedback, convolutional encoders, where each constituent encoder processes the information bits in a different order due to a turbo interleaver.

A turbo code typically consists of a concatenation of at least two or more systematic codes. The systematic code generates multiple bits from an information bit, or systematic bit. One bit of the multiple bits generated is identical to the information bit. The systematic codes used for turbo encoding are typically comprised of recursive convolutional codes, also known as constituent codes, where each constituent code is generated by an encoder that associates at least one parity data bit with one systematic, or information bit. The systematic bit is merely one bit of the data to be transmitted, and the parity data bit is generated by the encoder from a linear combination of the systematic bit and previous systematic bits. The bit order of the systematic bits presented to each of the encoders is randomized with respect to that of a first encoder by the interleaver, so the transmitted signal contains the same information bits in different time slots. Interleaving the same information bits in different time slots provides uncorrelated noise on the parity bits. A parser may be included in the stream of systematic bits to divide the stream of systematic bits into parallel streams of subsets of systematic bits presented to each interleaver and encoder. The parallel constituent codes are concatenated to form a turbo code, or alternatively, a parsed parallel concatenated convolutional code.

In a turbo code built as a parallel concatenation of two constituent recursive convolutional codes, the turbo interleaver re-orders the input data sequence in a pseudo-random fashion prior to encoding by a second constituent code. The separate encoding produced by the two constituent encoders are uncorrelated, which allows them to be combined by a turbo encoder to produce a composite encoding with excellent error protection capability.

The resulting composite encoding is received via a transmission path by a turbo decoder based forward error correction (FEC) system. Unlike conventional convolutional decoders, such as the Viterbi decoder that decodes incoming data a bit at a time, a turbo decoder decodes a block, or frame, of data at a time. Hence, turbo decoders require incoming data to be synchronized to turbo frame boundaries for optimal performance. However, incoming data to the decoder from the modulator may contain errors, significantly complicating attempts to develop a successful synchronization scheme. Such errors may result in an incorrect determination that synchronization has occurred.

With properly synchronized data, turbo codes exhibit excellent error correction capabilities at low signal-to-noise ratios (SNR), and flexibility in trading off bit error rate (BER) and frame error rate performance to processing delay. Turbo codes have been demonstrated to yield bit error rate performance close to the theoretical limit for useful classes of idealized channels. As shown in FIG. 1, a concatenated turbo + Reed-Solomon (RS) coding system recommended for certain forward link systems includes a transmission path 116 through which data is processed. The transmission path 116 couples a block code encoder 102 to an interleaver 104 and a turbo encoder 106 in series to produce an output. A series coupled turbo decoder 110, deinterleaver 112 and block code decoder 114 receives the output via a transmission channel 108. The coding system illustrated in FIG. 1 serves to keep the outer RS code and outer interleaver parameters of certain forward links intact, and only the inner convolutional code is replaced by turbo codes.

In certain forward link concatenated system data, the first byte out of 188 bytes, is used as the frame marker byte. Synchronization is declared if three consecutive frame marker bytes are recognized. Moreover synchronization needs to be achieved only before RS decoding 114 since Viterbi decoders operate in a continuous fashion.

When the inner convolutional code is replaced by turbo codes, frame synchronization must be achieved before turbo decoding 110 due to the blockwise decoding measures of turbo codes. Therefore, the received “noisy” frame marker bytes are more unreliable compared to certain systems in which frame synchronization is acquired after Viterbi decoding. More than three frame marker bytes are required to achieve acceptable performance.

In the coding system shown in FIG. 1, the frame marker bytes are encoded by both RS and convolutional codes. With turbo coded concatenated systems, there are two options. The frame marker bytes may be uncoded or turbo coded. When frame marker bytes are turbo coded, frame synchronization declared before turbo decoding may be verified with higher reliability after turbo decoding. However, achieving frame synchronization is difficult, especially for low rates such as ½, since operating SNR is very low. When coding the frame marker bytes by the systematic turbo codes, a few extra parity bits from the first constituent encoder may be used advantageously. The parity bits of the first constituent encoder are useful during frame synchronization search mode, since input bits to the encoder are not turbo interleaved. The parity bits of the first constituent encoder corresponding to the frame marker bytes are known, provided the frame marker bytes are placed at the beginning of the frames. Moreover the number of extra parity bits coming from the first constituent encoder is larger for lower rate codes, which operate at lower SNR. For example, each frame marker byte is accompanied by four parity bits coming from the first constituent encoder for rate ½ turbo codes, two parity bits for rate ⅔ turbo codes and one parity bit for rate ¾ and ⅚ turbo codes. The number of these parity bits may be increased up to eight at the expense of an irregular puncturing pattern and some performance loss. Although it has no effect on the turbo frame synchronization performance, the frame marker bytes may also be coded by RS to imitate the certain operations.

In the coding system shown in FIG. 1, the probability of correct synchronization determination P_{d} and incorrect synchronization determination P_{f} may be calculated as shown in equations (1) and (2) respectively. In equations (1) and (2), e represents the maximum number of bits allowed to be in error in an L bit long cumulative frame marker sequence and still declare frame synchronization. In the equations,

$$\begin{matrix}{P}_{d} = {\sum }_{i = 0}^{e} ( \begin{matrix}L \\ i\end{matrix} ) {( 1 - p )}^{L - i} {p}^{i} & ( 1 ) \\ {P}_{f} = {\sum }_{i = 0}^{e} ( \begin{matrix}L \\ i\end{matrix} ) {( 0.5 )}^{L} & ( 2 )\end{matrix}$$

where,

L=F×N

and F represents the total number of frame markers,

N=12 for rate ½ turbo codes,

N=10 for rate ⅔ turbo codes, and

N=9 for rate ⅚ turbo codes.

element p represents the raw bit error probability before turbo decoding.

Where F=3 to 10 sets of frame markers, the probabilities P_{d} and P_{f} for rate ½, ⅔ and ⅚ turbo codes operating with certain forward link parameters are given below in Tables 1 through 3, respectively. The calculated raw bit error probabilities before turbo decoding corresponding to concatenated BER=10⁻¹⁰ is,

p=0.113 for rate ½ turbo codes,

p=0.058 for rate ⅔ turbo codes, and

p=0.018 for rate ⅚ turbo codes.

TABLE 1
P_{d} versus P_{f} for rate ½ turbo codes, p = 0.113

| | e | P_{d} | P_{f} |
|---|---|---|---|
| L = 3 × 12 | 6 | 0.89 | 3.48 × 10⁻⁵ |
| | 7 | 0.96 | 1.56 × 10⁻⁴ |
| | 8 | 0.983534 | 5.97 × 10⁻⁴ |
| | 9 | 0.994636 | 1.97 × 10⁻³ |
| L = 4 × 12 | 7 | 0.83 | 3.12 × 10⁻⁷ |
| | 8 | 0.91 | 1.65 × 10⁻⁶ |
| | 9 | 0.96 | 7.61 × 10⁻⁶ |
| | 10 | 0.983664 | 3.08 × 10⁻⁵ |
| L = 5 × 12 | 9 | 0.86 | 1.54 × 10⁻⁸ |
| | 10 | 0.93 | 8.08 × 10⁻⁸ |
| | 11 | 0.96 | 3.78 × 10⁻⁷ |
| | 12 | 0.984808 | 1.59 × 10⁻⁶ |
| L = 6 × 12 | 12 | 0.94 | 4.03 × 10⁻⁹ |
| | 13 | 0.97 | 1.90 × 10⁻⁸ |
| | 14 | 0.986334 | 8.23 × 10⁻⁸ |
| | 15 | 0.994107 | 3.27 × 10⁻⁷ |
| L = 7 × 12 | 17 | 0.994556 | 1.75 × 10⁻⁸ |
| | 18 | 0.997693 | 6.66 × 10⁻⁸ |
| | 19 | 0.999082 | 2.37 × 10⁻⁷ |
| | 20 | 0.999657 | 7.92 × 10⁻⁷ |
| L = 8 × 12 | 20 | 0.997823 | 3.66 × 10⁻⁹ |
| | 21 | 0.999089 | 1.35 × 10⁻⁸ |
| | 22 | 0.999639 | 4.72 × 10⁻⁸ |
| | 23 | 0.999864 | 1.56 × 10⁻⁷ |
| L = 9 × 12 | 23 | 0.999127 | 1.99 × 10⁻¹⁰ |
| | 24 | 0.999639 | 2.74 × 10⁻⁹ |
| | 25 | 0.999857 | 9.41 × 10⁻⁹ |
| | 26 | 0.999946 | 3.07 × 10⁻⁸ |
| | e | P_{d} | P^{f} |
| L = 10 × 12 | 26 | 0.999649 | 1.57 × 10⁻¹⁰ |
| | 27 | 0.999856 | 5.57 × 10⁻¹⁰ |
| | 28 | 0.999943 | 1.88 × 10⁻⁹ |
| | 29 | 0.999979 | 6.09 × 10⁻⁹ |

TABLE 2
P_{d} versus P_{f} for rate ⅔ turbo codes, p = 0.058

| | e | P_{d} | P_{f} |
|---|---|---|---|
| L = 3 × 10 | 3 | 0.91 | 4.22 × 10⁻⁶ |
| | 4 | 0.97 | 2.97 × 10⁻⁵ |
| | 5 | 0.993240 | 1.62 × 10⁻⁴ |
| | 6 | 0.998627 | 7.15 × 10⁻⁴ |
| L = 4 × 10 | 5 | 0.97 | 6.91 × 10⁻⁷ |
| | 6 | 0.992423 | 4.18 × 10⁻⁶ |
| | 7 | 0.998154 | 2.11 × 10⁻⁵ |
| | 8 | 0.999610 | 9.11 × 10⁻⁵ |
| L = 5 × 10 | 6 | 0.975 | 1.62 × 10⁻⁸ |
| | 7 | 0.992287 | 1.05 × 10⁻⁷ |
| | 8 | 0.997877 | 5.82 × 10⁻⁷ |
| | 9 | 0.999483 | 2.81 × 10⁻⁶ |
| L = 6 × 10 | 7 | 0.978 | 3.84 × 10⁻¹⁰ |
| | 8 | 0.992544 | 2.60 × 10⁻⁹ |
| | 9 | 0.997758 | 1.54 × 10⁻⁸ |
| | 10 | 0.999395 | 8.08 × 10⁻⁸ |
| L = 7 × 10 | 8 | 0.980392 | 9.13 × 10⁻¹² |
| | 9 | 0.993013 | 6.42 × 10⁻¹¹ |
| | 10 | 0.997753 | 4.00 × 10⁻¹⁰ |
| | 11 | 0.999345 | 2.23 × 10⁻⁹ |
| L = 8 × 10 | 10 | 0.993583 | 1.58 × 10⁻¹² |
| | 11 | 0.997824 | 1.02 × 10⁻¹¹ |
| | 12 | 0.999325 | 6.01 × 10⁻¹¹ |
| | 13 | 0.999809 | 3.21 × 10⁻¹⁰ |
| L = 9 × 10 | 11 | 0.994186 | 3.89 × 10⁻¹⁴ |
| | 12 | 0.997942 | 2.60 × 10⁻¹³ |
| | 13 | 0.999329 | 1.59 × 10⁻¹² |
| | 14 | 0.999799 | 8.89 × 10⁻¹² |
| L = 10 × 10 | 12 | 0.994783 | 9.56 × 10⁻¹⁶ |
| | 13 | 0.998086 | 6.56 × 10⁻¹⁵ |
| | 14 | 0.999349 | 4.14 × 10⁻¹⁴ |
| | 15 | 0.999796 | 2.41 × 10⁻¹³ |

TABLE 3
P_{d} versus P_{f} for rate ⅚ turbo codes, p = 0.018

| | e | P_{d} | P_{f} |
|---|---|---|---|
| L = 3 × 9 | 0 | 0.61 | 7.45 × 10⁻⁹ |
| | 1 | 0.92 | 2.09 × 10⁻⁷ |
| | 2 | 0.987646 | 2.82 × 10⁻⁶ |
| | 3 | 0.998677 | 2.46 × 10⁻⁵ |
| L = 4 × 9 | 1 | 0.86 | 5.38 × 10⁻¹⁰ |
| | 2 | 0.97 | 9.71 × 10⁻⁹ |
| | 3 | 0.996095 | 1.14 × 10⁻⁷ |
| | 4 | 0.999552 | 9.71 × 10⁻⁷ |
| L = 5 × 9 | 2 | 0.95 | 2.94 × 10⁻¹¹ |
| | 3 | 0.991304 | 4.33 × 10⁻¹⁰ |
| | 4 | 0.998732 | 4.67 × 10⁻⁹ |
| | 5 | 0.999848 | 3.94 × 10⁻⁸ |
| L = 6 × 9 | 3 | 0.98 | 1.46 × 10⁻¹² |
| | 4 | 0.997127 | 1.90 × 10⁻¹¹ |
| | 5 | 0.999581 | 1.95 × 10⁻¹⁰ |
| | 6 | 0.999948 | 1.63 × 10⁻⁹ |
| L = 7 × 9 | 4 | 0.994407 | 6.91 × 10⁻¹⁴ |
| | 5 | 0.999039 | 8.31 × 10⁻¹³ |
| | 6 | 0.999859 | 8.20 × 10⁻¹² |
| | 7 | 0.999982 | 6.82 × 10⁻¹¹ |
| L = 8 × 9 | 5 | 0.998073 | 3.19 × 10⁻¹⁵ |
| | 6 | 0.999675 | 3.63 × 10⁻¹⁴ |
| | 7 | 0.999952 | 3.48 × 10⁻¹³ |
| | 8 | 0.999993 | 2.88 × 10⁻¹² |
| L = 9 × 9 | 6 | 0.999334 | 1.46 × 10⁻¹⁶ |
| | 7 | 0.999889 | 1.58 × 10⁻¹⁵ |
| | 8 | 0.999983 | 1.49 × 10⁻¹⁴ |
| | 9 | 0.999997 | 1.23 × 10⁻¹³ |
| L = 10 × 9 | 7 | 0.999769 | 6.58 × 10⁻¹⁸ |
| | 8 | 0.999962 | 6.92 × 10⁻¹⁷ |
| | 9 | 0.999994 | 6.40 × 10⁻¹⁶ |

Given the probabilities of false locks in turbo decoder systems, where turbo decoders require incoming data to be synchronized to turbo frame boundaries for optimal performance, a need exists for a system and method of synchronization and maximum error detection that compromises between synchronization time and probability of false lock.

### SUMMARY OF THE INVENTION

An object of the present invention is to provide a system and method for frame synchronization in turbo decoder based forward error correction (FEC) systems, through the use of a programmable conditional synchronizer module. The conditional synchronizer module is adapted to receive data from a demodulator and determine a synchronization level and conditional synchronization condition prior to transmittal to a turbo decoder.

Another object of the present invention is to provide a method and system for frame synchronization through the use of a programmable sync check 1 module adapted to monitor data output from a turbo decoder.

A further object of the present invention is to provide a method and system for frame synchronization through the use of a programmable sync check 2 module adapted to monitor data output from a block code decoder in concatenated FEC systems.

Still another object of the present invention is to provide a method and system for frame synchronization in which the probability of false locks is minimized through the combined use of a conditional synchronizer module, a sync check 1 module and a sync check 2 module.

These and other objects are substantially achieved by an embodiment of the present invention, which provides a practical and easily implemented solution to turbo decoder synchronization detection. The embodiment is applicable to any turbo decoder based system, including concatenated systems in which the turbo decoder is followed by a block decoder, such as the Reed-Solomon decoder. By providing the ability to configure the synchronization detection system through the use of programmable registers, the embodiment of the invention may be parameterized to work in various operating conditions. Furthermore, the embodiment includes a practical hardware solution that can be easily implemented in an integrated circuit.

### BRIEF DESCRIPTION OF THE DRAWINGS

These and other objects, features and characteristics of the present invention will become more apparent to those skilled in the art from a study of the following detailed description in conjunction with the appended claims and drawings, all of which form a part of this specification. In the drawings:

FIG. 1 is a block diagram illustrating an example of a concatenated system for a forward link;

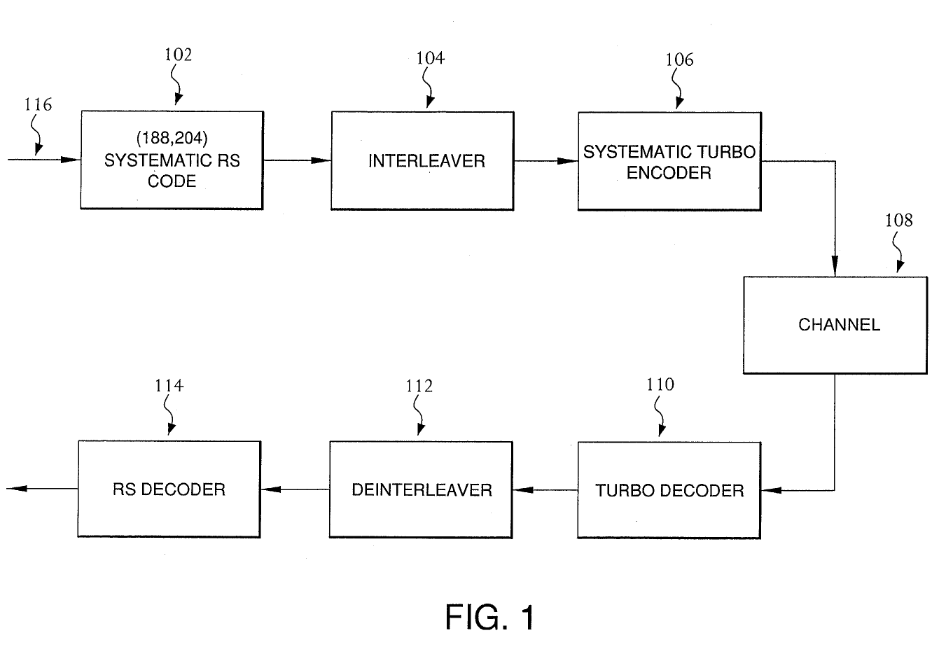

FIG. 2 is a block diagram in accordance with an embodiment of the present invention illustrating an example of the implementation of a configurable conditional synchronizer module with an additional first and second sync check module providing a synchronization scheme of a turbo decoder based FEC system; and

FIG. 3 is a block diagram illustrating a test environment for use in illustrating an example of the operation of an embodiment of the present invention.

### DETAILED DESCRIPTION OF THE PREFERRED EMBODIMENTS

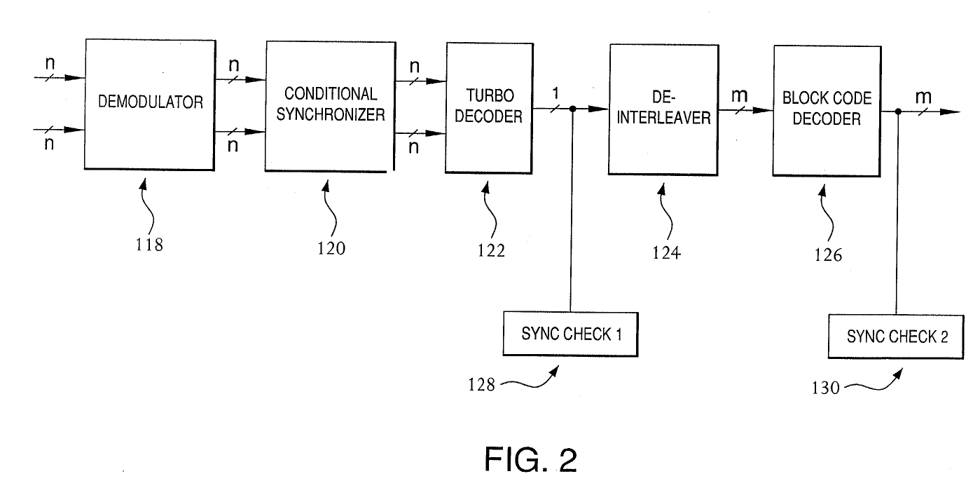

FIG. 2 illustrates the synchronization scheme in accordance with an embodiment of the present invention. In FIG. 2, three modules are used to monitor synchronization in the turbo decoder based FEC system. The conditional synchronizer module 120 receives noisy I, Q data from demodulator 118 and searches for “conditional synchronization” depending on configurable criteria. The criteria may include the number of consecutive frame markers used to determine synchronization (F), in addition to the maximum number of bits (e) allowed to be in error in the cumulative frame marker sequence. These variables may be stored in registers and edited using software adapted to the process.

Conditional synchronization within conditional synchronizer module 120 is declared if, for X+1 sets of frame markers in a row, each has less than or equal to e total errors. The value of X is configurable from 0 to 7, with each set consisting of 8 consecutive frame markers, and the value of e is configurable from 0 to 31. The frame size and marker size and format depends on the rate. Variable ranges are presented as an example for use in the embodiment shown, however values may be adjusted for different applications. The programmable configuration options allow flexibility declaring conditional synchronization, and may also be edited using software adapted to the process. However, if the requirements for conditional synchronization are met within conditional synchronizer module 120, when in fact synchronization has not occurred, a “false lock” condition is created. A false lock condition often occurs due to errors in the incoming data to the decoder from the demodulator. In this case, the conditional synchronization declared is incorrect, and sync check 1 module 128 and sync check 2 module 130 serve to detect the error and reset the FEC system.

Once conditional synchronization is achieved, data is passed to the turbo decoder 122 for error correction. The sync check 1 module 128 monitors data out of turbo decoder 122 and provides a secondary synchronization check to insure a false lock has not occurred. In a concatenated FEC system, in which the turbo decoder 122 is followed by a block code decoder 126, such as a Reed-Solomon decoder, a third synchronization check is provided, monitoring data at the output of the block decoder 126 via the sync check 2 module 130.

Sync check 1 module 128 monitors the output of the turbo decoder 122 and “sync” is declared if S sync bytes in a row from the turbo decoder 122 match Y+5 bits out of 8, where the values of S and Y are configurable from 0 to 3. Therefore, sync check 1 module 128 prevents the FEC system from a false lock condition allowed by conditional synchronizer module 120. If a sync condition is not declared by the sync check 1 module 128, module 128 resets the FEC system, forcing the system to go back and search for conditional synchronization again. As with the conditional synchronizer module 120, the programmable configurations for S and Y allow flexibility declaring a sync condition. Also, the variable ranges are presented as an example for use in the embodiment shown and the values may be adjusted for different applications and may be edited using software adapted to the process.

In the case of a concatenated FEC system where the turbo decoder is followed by a block code decoder, the sync check 2 module 130 monitors the m-bit wide output of the block code decoder 126, and sync declared by module 128 is lost if the block code decoder 126 generates Z error sets in a row as detected by module 130. Each error set is T or more uncorrectable frames out of 4, where T is programmable from 1 to 4 and Z is programmable to values 1, 2, 4, 8 or 16. The variable ranges are presented as an example for use in the embodiment shown and the values may be adjusted for different applications and may be edited using software adapted to the process. The sync check 2 module 130 will reset the FEC system when sync declared by module 128 is lost, forcing the system to go back and search for conditional synchronization. As with the conditional synchronizer module 120 and sync check 1 module 128, the programmable configurations for variables Z and T allow flexibility in the application of the sync check 2 module.

In the embodiment shown in FIG. 2, the bit error rate (BER) after turbo decoder 122 is 10⁻⁴ or lower, and is 10⁻¹⁰ or lower after the block decoder 126. Using both sync check 1 and sync check 2 modules 128 and 130, the probability of false lock is reduced considerably. The accuracy of the conditional synchronization declaration by module 120 is greatly improved in that false locks are detected by modules 128 and 130, forcing a reset of the system. Once reset, the conditional synchronizer module 120 searches for conditional synchronization again. As the BER after the turbo decoder 122 and block code decoder 126 is very low, the error detection rate is very high. Therefore corrupt frame markers are largely prevented from disrupting the system.

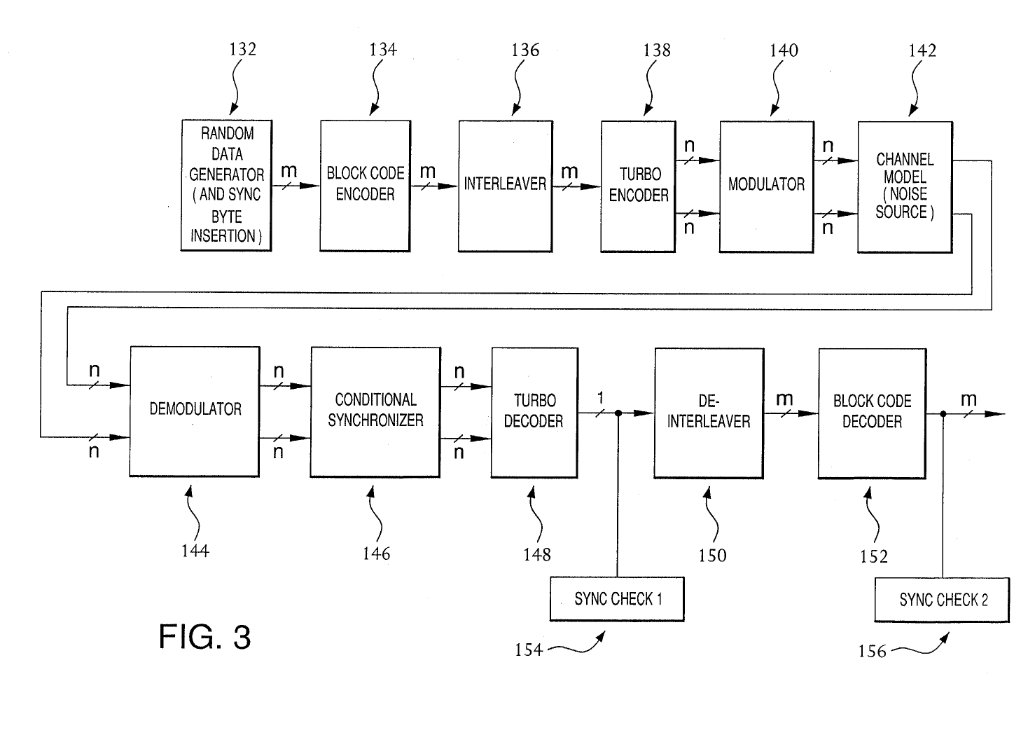

In a test environment shown in FIG. 3, the introduction of channel noise through a source model 142 is used to illustrate the operation of the conditional synchronizer module 146 and sync check modules 154 and 156. Random data inserted with frame markers is processed through a communication network comprised of block code encoder 134, followed by interleaver 136 and by turbo encoder 138. The data output of turbo encoder 138 is then processed through a modulator 140 and finally through a transmission channel model 142 where noise is introduced to the signal. The I, Q data is then received and processed through demodulator 144 and the turbo decoder based FEC system, comprised of the conditional synchronizer 146, turbo decoder 148, deinterleaver 150, and block code decoder 152. The addition of sync check 1 and 2 modules 154 and 156, detect and force correction of false locks by the conditional synchronizer 146.

In FIG. 3, the embodiment of the present invention tested at code rates ½, ⅔, ¾, ⅘, and ⅚, and at different SNR points, resulted in correct synchronization in all cases. Parameter e, which represents the maximum number of bits allowed to be in error within a frame marker sequence, was varied according to the predicted raw bit error probability p at the various SNR points. When a sufficient number of good frames of data issue, such that the conditional synchronization module 146 declares a conditional synchronization condition (minimally), frame markers on subsequent frames when corrupted, are detected by sync check 1 module 154 and prevent module 154 from declaring a sync condition exists. In other words, when a minimal number of corrupted frames are used to create a false lock by the conditional synchronizer module 146, sync check 1 module 154 effectively and accurately detects the condition and resets the FEC system.

Furthermore, when a sufficient number of good frames of data are issued such that sync check 1 module 154 declares a sync condition (minimally), frame markers on subsequent frames when corrupted, are detected by sync check 2 module 156 and force module 156 to reset the system. By introducing the appropriate amount of noise (data corruption) in the channel model block 142, FIG. 3 allows for testing at different SNR points. Tests reveal that the use of the configurable conditional synchronization module 146 and sync check modules 154 and 156, provides a robust method to achieve and maintain synchronization throughout the FEC chain.

As the prevalence of turbo decoders is starting to increase in commercial applications, this embodiment of the present invention has significant commercial value as it is widely applicable to any turbo decoder based FEC system under various operating conditions. By using this synchronization scheme, the turbo decoder based FEC system is able to give a significant coding gain (approximately 1 dB) over the DVB based FEC decoder used in many systems. The coding gain translates into capacity increase at the same cost, i.e. more users per satellite.

Although only a few exemplary embodiments of the present invention have been described in detail above, those skilled in the art will readily appreciated that many modifications are possible in the exemplary embodiments without materially departing from the novel teachings and advantages of this invention. Accordingly, all such modifications are intended to be included within the scope of this invention as defined in the following claims.

What is claimed is:

1. A method for determining synchronization between incoming data and turbo frame boundaries in a turbo decoder based forward error correction system, said system comprising a turbo decoder adapted to receive incoming data and provide a turbo decoder output, an optional deinterleaver adapted to receive said turbo decoder output and provide a deinterleaver output, and an optional block code decoder adapted to receive said deinterleaver output and provide a block code decoder output, the method comprising:
performing a first synchronization check of said incoming data frame markers to said turbo decoder, resulting in a conditional synchronization declaration if a first condition is met, said declaration being required to allow transfer of data to said turbo decoder;
performing optionally one or both of the following two operations:
a second synchronization check of sync bytes from said turbo decoder output, resulting in resetting said conditional synchronization declaration if a second condition is not met; and
a third synchronization check of error sets from said block decoder output, resulting in resetting said conditional synchronization declaration if a third condition is met; and
repeating said first synchronization check if said conditional synchronization declaration is reset.

2. A method as claimed in claim 1, wherein said first condition is met if, for a certain number of data sets in a row, each has less than or equal to a certain number of errors, each data set comprising a certain number of consecutive frame markers in a row.

3. A method as claimed in claim 2, wherein said number of data sets, number of errors and number of consecutive frame markers are selectable.

4. A method as claimed in claim 1, wherein said second condition is met if a certain number of sync bytes in a row from said turbo decoder output match a certain number of bits from a total number of bits.

5. A method as claimed in claim 4, wherein said number of sync bits, number of bits and total number of bits are selectable.

6. A method as claimed in claim 1, wherein said third condition is met if said block decoder generates a certain number of error sets in a row, each error set comprising a certain number of uncorrectable data frames from a total number of data frames.

7. A method as claimed in claim 6, wherein said number of error sets, number of uncorrectable data frames and total number of data frames are selectable.

8. An apparatus adapted to determine synchronization between incoming data and turbo frame boundaries in a turbo decoder based forward error correction system, said system comprising a turbo decoder adapted to receive incoming data and provide a turbo decoder output, an optional deinterleaver adapted to receive said turbo decoder output and provide a deinterleaver output, and an optional block code decoder adapted to receive said deinterleaver output and provide a block code decoder output, the apparatus comprising:
a conditional synchronizer module, adapted to provide a first synchronization check of said incoming data frame markers to said turbo decoder, and being further adapted to declare conditional synchronization if a first condition is met, said declaration being required to allow transfer of data to said turbo decoder;
an optional first sync check module, adapted to provide a second synchronization check of sync bytes from said turbo decoder output, and being further adapted to reset said conditional synchronization declaration if a second condition is not met; and
an optional second sync check module, adapted to provide a third synchronization check of error sets from said block decoder output, and being further adapted to reset said conditional synchronization declaration if a third condition is met; and
wherein said conditional synchronizer module is further adapted to repeat said first synchronization check if said conditional synchronization declaration is reset.

9. An apparatus as claimed in claim 8, wherein said first condition is met if, for a certain number of data sets in a row, each has less than or equal to a certain number of errors, each data set comprising a certain number of consecutive frame markers in a row.

10. An apparatus as claimed in claim 9, wherein said number of data sets, number of errors and number of consecutive frame markers are selectable.

11. An apparatus as claimed in claim 8, wherein said second condition is met if a certain number of sync bytes in a row from said turbo decoder output match a certain number of bits from a total number of bits.

12. An apparatus as claimed in claim 11, wherein said number of sync bits, number of bits and total number of bits are selectable.

13. An apparatus as claimed in claim 8, wherein said third condition is met if said block decoder generates a certain number of error sets in a row, each error set comprising a certain number of uncorrectable data frames from a total number of data frames.

14. An apparatus as claimed in claim 13, wherein said number of error sets, number of uncorrectable data frames and total number of data frames are selectable.

15. A method for determining synchronization between incoming data and turbo frame boundaries in a turbo decoder based forward error correction system, said system comprising a turbo decoder adapted to receive incoming data and provide a turbo decoder output, an optional deinterleaver adapted to receive said turbo decoder output and provide a deinterleaver output, and an optional block code decoder adapted to receive said deinterleaver output and provide a block code decoder output, the method comprising:
performing a first synchronization check at said system turbo decoder input by monitoring said incoming data to said turbo decoder and declaring conditional synchronization if X+1 data sets in a row each have less than or equal to e errors, said declaration being required to allow transfer of data to said turbo decoder, and wherein said variables X and e are selectable;
performing optionally one or both of the following two operations:
a second synchronization check at said system turbo decoder output comprising monitoring said turbo decoder output and declaring first sync if S sync bytes in a row from said turbo decoder output match Y+5 bits of a total number of bits U and resetting said conditional synchronization declaration if first sync not declared, and wherein said variables S, Y and U are selectable; and
a third synchronization check at said system block code decoder output comprising monitoring said block decoder output and resetting said conditional synchronization declaration if said block decoder generates Z error sets in a row, where each said error set is T or more uncorrectable frames of a total number of frames V, said variables Z, T and V are selectable; and
repeating said first synchronization check if said conditional synchronization declaration is reset.

16. An apparatus for determining synchronization between incoming data and turbo frame boundaries in a turbo decoder based forward error correction system, said system comprising a turbo decoder adapted to receive incoming data and provide a turbo decoder output, an optional deinterleaver adapted to receive said turbo decoder output and provide a deinterleaver output, and an optional block code decoder adapted to receive said deinterleaver output and provide a block code decoder output, the apparatus comprising:
a conditional synchronizer module, adapted to provide a first synchronization check at said system turbo decoder input, and being further adapted to monitor said incoming data to said turbo decoder and declare conditional synchronization if X+1 data sets in a row each have less than or equal to e errors, said declaration being required to allow transfer of data to said turbo decoder, said variables X and e are selectable;
an optional first sync check module, adapted to monitor said turbo decoder output and declare first sync if S sync bytes in a row from said turbo decoder output match Y+5 bits of a total number of bits U, and being further adapted to reset said conditional synchronization declaration if first sync not declared, said variables S, Y and U are selectable; and
an optional second sync check module, adapted to monitor said block decoder output and reset said conditional synchronization declaration if said block decoder generates Z error sets in a row, where each said error set is T or more uncorrectable frames of a total number of frames V, said variables Z, T and V are selectable; and
wherein said conditional synchronizer module is further adapted to repeat said first synchronization check if said conditional synchronization declaration is reset.
